(19) United States
(12) Patent Application Publication
(10) Pub. No.: US 2025/0123557 A1
(43) Pub. Date: Apr. 17, 2025

(54) PHOTOACID GENERATOR, PHOTORESIST COMPOSITION COMPRISING THE SAME, RESIST LAYER, AND PATTERN FORMING METHOD

(71) Applicant: UNIVERSITY-INDUSTRY COOPERATION GROUP OF KYUNG HEE UNIVERSITY, Yongin-si (KR)

(72) Inventors: Jongwook PARK, Seoul (KR); Seunghyeon JO, Suwon-si (KR); Hyukmin GWON, Seongnam-si (KR); Kiho LEE, Seoul (KR); Sangwook PARK, Suwon-si (KR)

(21) Appl. No.: 18/915,651

(22) Filed: Oct. 15, 2024

(30) Foreign Application Priority Data
Oct. 16, 2023 (KR) 10-2023-0138003

(51) Int. Cl. G03F 7/004

(52) U.S. Cl. CPC G03F 7/0045

(57) ABSTRACT

Provided are a photoacid generator including a compound represented by Chemical Formula 1, a photoresist composition including the same, a resist layer formed using the same, and a method for forming a pattern from the resist layer.

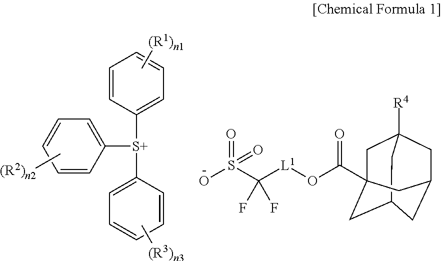

(The definition of Chemical Formula 1 is as described in the detailed description.)

### CROSS-REFERENCE TO RELATED APPLICATION

This application claims priority to and the benefit of Korean Patent Application No. 10-2023-0138003 filed in the Korean Intellectual Property Office on Oct. 16, 2023, the entire contents of which are incorporated herein by reference.

### BACKGROUND OF THE INVENTION

### (A) Field of the Invention

The present invention relates to a photoacid generator, a photoresist composition including the same, a resist layer, and a pattern forming method. The present invention is a result of three research projects, and specific information is as shown in Tables A to C.

TABLE A

| | |
|---|---|
| Assignment number | GRRC Kyunghee 2023-B01 |
| Name of Department | Gyeonggi-do |
| Name of task management | Gyeonggi Provincial Government |
| (professional) organization | |
| Research Project Name | Gyeonggi Regional Cooperation |
| | Research Center Project (GRRC) |
| Research Task Name | Development of advanced materials |
| | for sub-nm ultra-fine |
| | processes for implementing |
| | next-generation semiconductors |
| Contribution rate | ⅓ |
| Name of the organization | Kyunghee University Industry-Academic |
| performing the task | Cooperation Foundation |
| Research period | Jul. 1, 2023-Jun. 30, 2024 |

TABLE B

| | |
|---|---|
| Assignment unique number | 1345366155 |
| Assignment number | 2020R1A6A1A03048004 |
| Name of Department | Ministry of Education |
| Name of task management | National Research Foundation of Korea |
| (professional) organization | |
| Research Project Name | Establishment of a research foundation |
| | for science and engineering |
| Research Task Name | Display Components Materials Regional |
| | Innovation Center |
| Contribution rate | ⅓ |
| Name of the organization | Kyunghee University Industry-Academic |
| performing the task | Cooperation Foundation |
| Research period | Mar. 1, 2023-Feb. 29, 2024 |

TABLE C

| | |
|---|---|
| Assignment unique number | 1415187239 |
| Assignment number | 20017422 |
| Name of Department | Ministry of Trade, Industry and Energy |
| Name of task management | Korea Industrial Technology Assessment |
| (professional) organization | and Management Institute |
| Research Project Name | Material component technology development |
| Research Task Name | Development of raw material technology |
| | and process for ArFi resist |
| Contribution rate | ⅓ |
| Name of the organization | Kyung-In Synthetic Corporation |
| performing the task | |
| Research period | Jan. 1, 2023-Dec. 31, 2023 |

### (B) Description of the Related Art

In manufacturing highly integrated semiconductor devices, pattern miniaturization is essential. Recently, as a design rule of semiconductor devices has been rapidly decreasing, various lithography technologies are being developed to implement fine patterns. In particular, EUV lithography technology, which uses an exposure process by EUV with a wavelength of about 13.5 nm, is being extensively studied as next generation technology capable of replacing a lithography process by using a KrF excimer laser (about 248 nm) and an ArF excimer laser (about 193 nm).

The EUV lithography process works different from the lithography process by the KrF excimer laser and the ArF excimer laser. The EUV lithography process is entirely performed under vacuum. In EUV lithography equipment, because power required to irradiate a laser from a light source is insufficient, there is a limit to make a dose large enough to generate a required amount of acid from a photoacid generator of a resist material during the exposure.

However, when the EUV lithography process is performed by using a resist material including a conventional photoacid generator, it is difficult to obtain desired exposure sensitivity and resolution due to low acid generation efficiency and a low exposure speed, which are caused by a low dose provided from the light source of the EUV lithography equipment.

Therefore, there is still a need for a novel photoacid generator having excellent lithography characteristics such as exposure sensitivity and resolution and an excellent pattern shape, a photoresist composition including the same, and a method of manufacturing the photoacid generator.

### SUMMARY OF THE INVENTION

An embodiment provides a novel photoacid generator capable of providing excellent patterning performance.

Another embodiment provides a photoresist composition including the photoacid generator.

Another embodiment provides a resist layer formed using the photoresist composition.

Another embodiment provides a method for forming a pattern of excellent shape from the resist layer.

According to an embodiment, a photoacid generator including a compound represented by Chemical Formula 1 is provided.

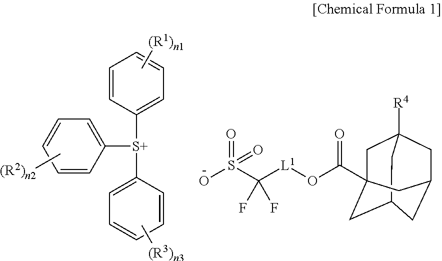

In Chemical Formula 1,

R¹ to R⁴ are each independently a halogen atom, a hydroxy group, a substituted or unsubstituted C1 to C20 alkyl group, a substituted or unsubstituted C1 to C20 alkoxy group, a substituted or unsubstituted C3 to C20 cycloalkyl group, a substituted or unsubstituted C6 to C20 aryl group, or a substituted or unsubstituted C2 to C20 heterocyclic group,

L¹ is a single bond, a substituted or unsubstituted C1 to C20 alkylene group or a substituted or unsubstituted C6 to C20 arylene group, and

n1 to n3 are each independently an integer from 0 to 5, provided that n1+n2+n3≠0.

Chemical Formula 1 may be represented by Chemical Formula 1-1.

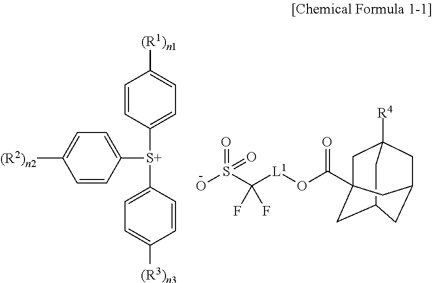

In Chemical Formula 1-1,

R¹ to R⁴ are each independently a halogen atom, a hydroxy group, a substituted or unsubstituted C1 to C20 alkyl group, a substituted or unsubstituted C1 to C20 alkoxy group, a substituted or unsubstituted C3 to C20 cycloalkyl group, a substituted or unsubstituted C6 to C20 aryl group, or a substituted or unsubstituted C2 to C20 heterocyclic group,

L¹ is a single bond, a substituted or unsubstituted C1 to C20 alkylene group or a substituted or unsubstituted C6 to C20 arylene group, and

n1 to n3 are each independently an integer of 0 or 1, provided that n1+n2+n3≠0.

The n1+n2+n3 may be 1.

The n1 may be an integer of 1, and the n2 and n3 may each independently be an integer of 0.

R¹ to R³ may each independently be a substituted or unsubstituted C1 to C20 alkyl group.

R⁴ may be a hydroxy group.

L¹ may be a substituted or unsubstituted C1 to C20 alkylene group.

The compound represented by Chemical Formula 1 may be represented by 5 Chemical Formula 1A, Chemical Formula 1B, or Chemical Formula 1C.

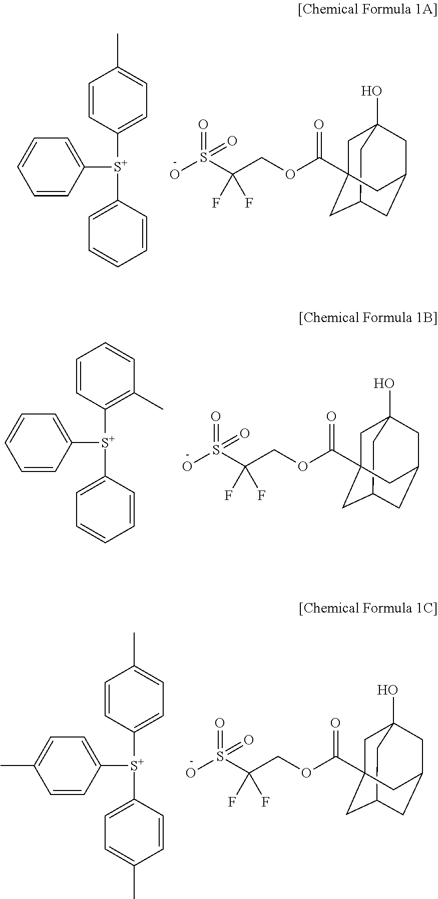 [SMILES: Cc1ccc([S+](c2ccccc2)c2ccccc2)cc1 ; O=C(OCC(F)(F)S(=O)(=O)O)C12CC3CC(CC(O)(C3)C1)C2 ; Cc1ccccc1[S+](c1ccccc1)c1ccccc1 ; O=C(OCC(F)(F)S(=O)(=O)O)C12CC3CC(CC(O)(C3)C1)C2 ; Cc1ccc([S+](c2ccc(C)cc2)c2ccc(C)cc2)cc1 ; O=C(OCC(F)(F)S(=O)(=O)O)C12CC3CC(CC(O)(C3)C1)C2]

According to another embodiment, a photoresist composition includes a resin; the photoacid generator; and a solvent.

The above resin may include an acrylic resin.

The photoresist composition may include about 5 wt % to about 20 wt % of the resin; about 0.1 wt % to about 5 wt % of the photoacid generator; and a balance amount of the solvent, based on a total amount of the photoresist composition.

According to another embodiment, a resist layer formed using the photoresist composition is provided.

According to another embodiment, a method for forming a pattern includes exposing the resist layer; and developing the exposed resist layer.

By using a photoacid generator according to an embodiment of the present invention, a pattern having an excellent shape can be obtained.

### BRIEF DESCRIPTION OF THE DRAWINGS

FIG. 1 is an NMR graph of a photoacid generator according to Comparative Example 1.

FIG. 2 is a DSC curve graph of a photoacid generator according to Comparative Example 1.

FIG. 3 is a TGA curve graph of a photoacid generator according to Comparative Example 1.

FIG. 4 is an NMR graph of a photoacid generator according to Example 1.

FIG. 5 is a DSC curve graph of a photoacid generator according to Example 1.

FIG. 6 is a TGA curve graph of a photoacid generator according to Example 1.

FIG. 7 is an NMR graph of a photoacid generator according to Example 2.

FIG. 8 is a DSC curve graph of a photoacid generator according to Example 2.

FIG. 9 is a TGA curve graph of a photoacid generator according to Example 2.

FIG. 10 is an NMR graph of a photoacid generator according to Example 3.

FIG. 11 is a DSC curve graph of a photoacid generator according to Example 3.

FIG. 12 is a TGA curve graph of a photoacid generator according to Example 3.

FIG. 13 is a photograph of a pattern formed from the photoresist composition according to Comparative Example 3.

FIG. 14 is a photograph of a pattern formed from the photoresist composition according to Comparative Example 4.

FIG. 15 is a photograph of a pattern formed from the photoresist composition according to Example 4.

FIG. 16 is a photograph of a pattern formed from the photoresist composition according to Example 5.

FIG. 17 is a photograph of a pattern formed from the photoresist composition according to Example 6.

### DETAILED DESCRIPTION OF THE EMBODIMENTS

Hereinafter, embodiments of the present invention are described in detail. However, these embodiments are exemplary, and this disclosure is not limited thereto.

As used herein, when a definition is not otherwise provided, “substituted” refers to replacement of at least one hydrogen of a substituent or a compound by deuterium, NH₂, a C1 to C4 amine group, a nitro group, a C1 to C4 silyl group, a C1 to C4 alkyl group, a C1 to C4 alkylsilyl group, a C1 to C4 alkoxy group, a fluoro group, a C1 to C4 trifluoroalkyl group, or a cyano group.

As used herein, when a definition is not otherwise provided, “hetero” refers to inclusion of 1 to 4 heteroatoms selected from, N, O, S, Se, Te, Si, and P.

As used herein, when a definition is not otherwise provided, “aryl group” refers to a group including at least one hydrocarbon aromatic moiety. All the elements of the hydrocarbon aromatic moiety have p-orbitals which form conjugation, for example a phenyl group, a naphthyl group, and the like, two or more hydrocarbon aromatic moieties may be linked by a sigma bond, for example a biphenyl group, a terphenyl group, a quarterphenyl group, and the like, and two or more hydrocarbon aromatic moieties are fused directly or indirectly to provide a non-aromatic fused ring, for example a fluorenyl group. The aryl group may include a monocyclic, polycyclic or fused polycyclic (i.e., rings sharing adjacent pairs of carbon atoms) functional group.

As used herein, when a definition is not otherwise provided, “heteroaryl group” refers to an aryl group including at least one heteroatom selected from N, O, S, Se, Te, P, and Si instead of carbon (C) in the ring. When the heteroaryl group is a fused ring, at least one of rings of the heteroaryl group may have a heteroatom or each ring may have a hetero atom.

As used herein, when a definition is not otherwise provided, “*” refers to a linking point between the same or different atoms, or chemical formulas.

Throughout this specification, references to “one embodiment,” “an embodiment,” “an exemplary embodiment,” and the like mean that a particular element described in connection with the embodiment is included in at least one embodiment described herein and may or may not be present in other embodiments. It should also be understood that the described elements may be combined in any suitable manner in various embodiments.

Unless otherwise defined, technical and scientific terms used herein have the same meaning as commonly understood by one of ordinary skill in the art to which this application belongs. All patents, patent applications, and other references cited are incorporated herein by reference in their entirety. However, if a term in this specification contradicts or conflicts with a term in an incorporated reference, the term from this specification shall take precedence over the conflicting term in the incorporated reference. Although specific examples and embodiments have been described, presently unanticipated or unforeseen alternatives, modifications, variations, improvements and substantial equivalents may occur to applicants or those skilled in the art. Accordingly, the appended claims and their amendments are intended to include all such alternatives, modifications, improvements, and substantial equivalents. Hereinafter, a photoacid generator according to an embodiment is described.

According to an embodiment, a photoacid generator may include a compound represented by Chemical Formula 1.

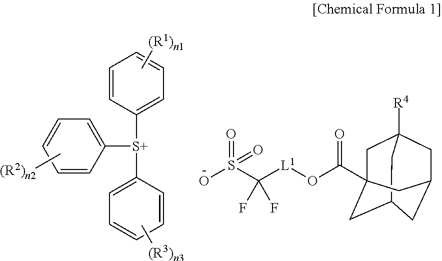

In the above Chemical Formula 1,

R¹ to R⁴ are each independently a halogen atom, a hydroxy group, a substituted or unsubstituted C1 to C20 alkyl group, a substituted or unsubstituted C1 to C20 alkoxy group, a substituted or unsubstituted C3 to C20 cycloalkyl group, a substituted or unsubstituted C6 to C20 aryl group, or a substituted or unsubstituted C2 to C20 heterocyclic group,

L¹ is a single bond, a substituted or unsubstituted C1 to C20 alkylene group or a substituted or unsubstituted C6 to C20 arylene group, and n1 to n3 are each independently an integer from 0 to 5, provided that n1+n2+n3≠0.

The photoacid generator is a photoacid generator for a semiconductor photoresist, and in general, when a photoresist composition including the photoacid generator is used to form a positive type pattern, it is difficult to obtain an excellent pattern shape. The photoacid generator, when exposed to light, is decomposed and generates acid, which subsequently decomposes a polymer such as a resin, but if protons are released in the process that the photoacid generator is decomposed by receiving light, the photoacid generator may stably exist. In other words, the protons may or may not be released depending on a structure of the photoacid generator, wherein because too high stability of the photoacid generator also may rather negatively affect the formation of an excellent shape pattern, it is very important to develop a photoacid generator with the most optimal structure.

In particular, because the EUV light source (about 13.5 nm) has fewer photons than an ArF immersion light source, noises increase at a boundary between exposed region and non-exposed region by the EUV light source. In order to compensate for this, the lithography process by the EUV light source, compared with lithography processes by other light sources, requires a large amount of photoacid generator in a photoresist composition, based on the same dose of light. However, if a high content of the photoacid generator is included in the photoresist composition, a glass transition temperature (T_{g}) of a polymer resin may be changed, which may deteriorate thermal stability. In addition, the resolution of resist pattern formed during the lithography process by the EUV light source may be deteriorated by the residual photoacid generator.

However, the photoacid generator according to an embodiment has a structure represented by Chemical Formula 1 and thus, when the EUV light source is used to form a pattern, may not only excellent pattern resolution but also an excellent pattern shape even with the same or smaller light dose than when other light sources are used other than EUV.

For example, Chemical Formula 1 may be represented by Chemical Formula 1-1.

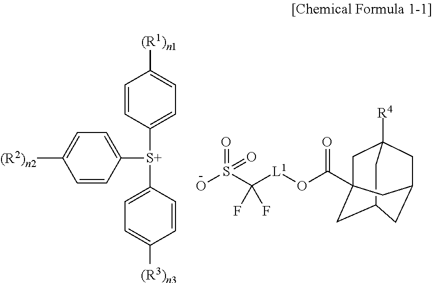

In Chemical Formula 1-1,

R¹ to R⁴ are each independently a halogen atom, a hydroxy group, a substituted or unsubstituted C1 to C20 alkyl group, a substituted or unsubstituted C1 to C20 alkoxy group, a substituted or unsubstituted C3 to C20 cycloalkyl group, a substituted or unsubstituted C6 to C20 aryl group, or a substituted or unsubstituted C2 to C20 heterocyclic group,

L¹ is a single bond, a substituted or unsubstituted C1 to C20 alkylene group or a substituted or unsubstituted C6 to C20 arylene group, and

n1 to n3 are each independently an integer of 0 or 1, provided that n1+n2+n3≠0.

For example, in Chemical Formula 1 and Chemical Formula 1-1, n1+n2+n3 may=1.

For example, in Chemical Formula 1 and Chemical Formula 1-1, n1 may be an integer of 1, and n2 and n3 may each independently be an integer of 0.

For example, in Chemical Formula 1 and Chemical Formula 1-1, R¹ to R³ may each independently be a substituted or unsubstituted C1 to C20 alkyl group.

For example, in Chemical Formula 1 and Chemical Formula 1-1, R⁴ may be a hydroxy group.

For example, in Chemical Formula 1 and Chemical Formula 1-1, L¹ may be a substituted or unsubstituted C1 to C20 alkylene group.

In this case, the shape of the positive type pattern that is finally formed can be made excellent.

For example, the compound represented by Chemical Formula 1 may be represented by Chemical Formula 1A, Chemical Formula 1B, or Chemical Formula 1C, but is not necessarily limited thereto.

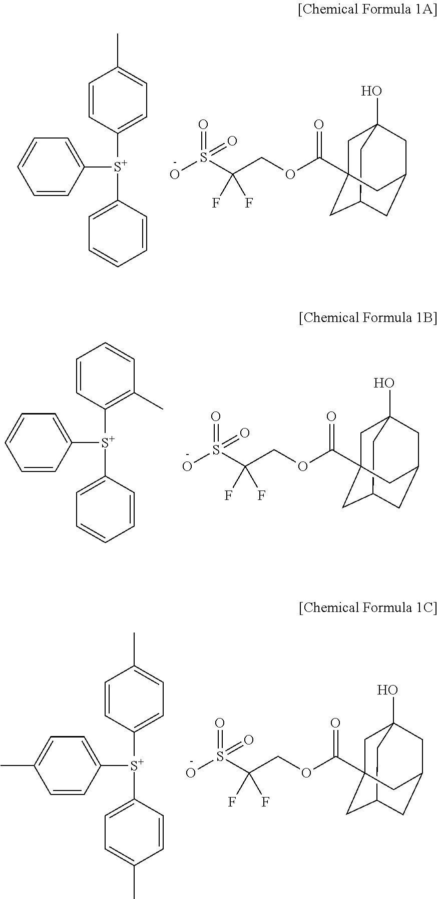 [SMILES: Cc1ccc([S+](c2ccccc2)c2ccccc2)cc1 ; O=C(OCC(F)(F)S(=O)(=O)O)C12CC3CC(CC(O)(C3)C1)C2 ; Cc1ccccc1[S+](c1ccccc1)c1ccccc1 ; O=C(OCC(F)(F)S(=O)(=O)O)C12CC3CC(CC(O)(C3)C1)C2 ; Cc1ccc([S+](c2ccc(C)cc2)c2ccc(C)cc2)cc1 ; O=C(OCC(F)(F)S(=O)(=O)O)C12CC3CC(CC(O)(C3)C1)C2]

A photoresist composition according to another embodiment further includes a resin and a solvent in addition to the photoacid generator.

The photoresist composition may provide excellent lithographic characteristics such as excellent exposure sensitivity and resolution and excellent pattern shape even under a small dosage by including the photoacid generator.

A content of the photoacid generator may be about 0.1 wt % to about 5 wt %, for example about 0.1 wt % to about 3 wt %, for example about 0.5 wt % to about 2 wt %, based on a total amount of the photoresist composition. If the content of the photoacid generator is less than about 0.1 wt % based on the total amount of the photoresist composition, the number of EUV photons may be reduced, resulting in a low light absorption rate. If the content of the photoacid generator exceeds about 5 wt % based on the total amount of the photoresist composition, the glass transition temperature (T_{g}) of the resin may change and the resolution of resist patterns formed during a lithography process using an EUV light source may deteriorate due to the photoacid generator remaining therein.

For example, the resin may include an acrylic resin.

The acrylic resin is a copolymer of a first ethylenically unsaturated monomer and a second ethylenically unsaturated monomer copolymerizable therewith, and is a resin including one or more acrylic repeating units.

The first ethylenically unsaturated monomer may be an ethylenically unsaturated monomer including at least one carboxyl group, and specific examples thereof include acrylic acid, methacrylic acid, maleic acid, itaconic acid, fumaric acid, or a combination thereof.

The first ethylenically unsaturated monomer may be included in an amount of about 5 wt % to about 50 wt %, for example about 10 wt % to about 40 wt %, based on a total amount of the acrylic resin.

Examples of the second ethylenic unsaturated monomer may include an aromatic vinyl compound such as styrene, a-methylstyrene, vinyltoluene, vinylbenzylmethylether, and the like; an unsaturated carboxylic acid ester compound such as methyl(meth)acrylate, ethyl(meth)acrylate, butyl(meth)acrylate, 2-hydroxyethyl (meth)acrylate, 2-hydroxy butyl(meth)acrylate, benzyl(meth)acrylate, cyclohexyl(meth)acrylate, phenyl(meth)acrylate, and the like; an unsaturated carboxylic acid amino alkyl ester compound such as 2-aminoethyl(meth)acrylate, 2-dimethylaminoethyl(meth)acrylate, and the like; a carboxylic acid vinyl ester compound such as vinyl acetate, vinyl benzoate, and the like; an unsaturated carboxylic acid glycidyl ester compound such as glycidyl(meth)acrylate and the like; a vinyl cyanide compound such as (meth)acrylonitrile and the like; an unsaturated amide compound such as (meth)acrylamide and the like; and the like, and may be used alone or as a mixture of two or more.

Specific examples of the acrylic resin may be a (meth)acrylic acid/benzylmethacrylate copolymer, a (meth)acrylic acid/benzylmethacrylate/styrene copolymer, a (meth)acrylic acid/benzylmethacrylate/2-hydroxyethylmethacrylate copolymer, a (meth)acrylic acid/benzylmethacrylate/styrene/2-hydroxyethylmethacrylate copolymer and the like, but are not limited thereto, and may be used alone or as a mixture of two or more.

The acrylic resin may have a weight average molecular weight of about 5,000 g/mol to about 15,000 g/mol. When the weight average molecular weight of the acrylic resin is within the above range, the physical and chemical properties of the photoresist composition are excellent and the viscosity is appropriate, which may be advantageous for pattern formation.

An acid value of the acrylic resin may be about 80 mgKOH/g to about 130 mgKOH/g. When the acid value of the acrylic resin is within the above range, the resolution of the pattern may be excellent.

For example, the resin may be included in an amount of about 5 wt % to about 20 wt %, for example about 5 wt % to about 15 wt %, based on a total amount of the photoresist composition. When the resin is included within the above range, the developability is excellent when forming a pattern, and the crosslinking property is improved, so that excellent pattern surface smoothness may be obtained.

For example, the solvent may include alcohols such as methanol, ethanol, and the like; ethers such as dichloroethyl ether, n-butyl ether, diisoamyl ether, methylphenyl ether, tetrahydrofuran, and the like; glycol ethers such as ethylene glycol monomethylether, ethylene glycol monoethylether, and the like; cellosolve acetates such as methyl cellosolve acetate, ethyl cellosolve acetate, diethyl cellosolve acetate, and the like; carbitols such as methylethyl carbitol, diethyl carbitol, diethylene glycol monomethylether, diethylene glycol monoethylether, diethylene glycol dimethylether, diethylene glycol methylethylether, diethylene glycol diethylether, and the like; propylene glycol alkylether acetates such as propylene glycol monomethylether acetate, propylene glycol propylether acetate, and the like; aromatic hydrocarbons such as toluene, xylene and the like; ketones such as methylethylketone, cyclohexanone, 4-hydroxy-4-methyl-2-pentanone, methyl-n-propylketone, methyl-n-butylketone, methyl-n-amylketone, 2-heptanone, and the like; saturated aliphatic monocarboxylic acid alkyl esters such as ethyl acetate, n-butyl acetate, isobutyl acetate, and the like; lactate esters such as methyl lactate, ethyl lactate, and the like; oxy acetic acid alkyl esters such as oxy methyl acetate, oxy ethyl acetate, butyl oxyacetate, and the like; alkoxy acetic acid alkyl esters such as methoxy methyl acetate, methoxy ethyl acetate, methoxy butyl acetate, ethoxy methyl acetate, ethoxy ethyl acetate, and the like; 3-oxy propionic acid alkyl esters such as 3-oxy methyl propionate, 3-oxy ethyl propionate, and the like; 3-alkoxy propionic acid alkyl esters such as 3-methoxy methyl propionate, 3-methoxy ethyl propionate, 3-ethoxy ethyl propionate, 3-ethoxy methyl propionate, and the like; 2-oxy propionic acid alkyl esters such as 2-oxy methyl propionate, 2-oxy ethyl propionate, 2-oxy propyl propionate, and the like; 2-alkoxy propionic acid alkyl esters such as 2-methoxy methyl propionate, 2-methoxy ethyl propionate, 2-ethoxy ethyl propionate, 2-ethoxy methyl propionate, and the like; 2-oxy-2-methyl propionic acid esters such 2-oxy-2-methyl methyl propionate, 2-oxy-2-methyl ethyl propionate, and the like, monooxy monocarboxylic acid alkyl esters of 2-alkoxy-2-methyl alkyl propionates such as 2-methoxy-2-methyl methyl propionate, 2-ethoxy-2-methyl ethyl propionate, and the like; esters such as 2-hydroxy ethyl propionate, 2-hydroxy-2-methyl ethyl propionate, hydroxy ethyl acetate, 2-hydroxy-3-methyl methyl butanoate, and the like; ketonate esters such as ethyl pyruvate, and the like. Additionally, high boiling point solvent such as N-methylformamide, N,N-dimethylformamide, N-methylformanilide, N-methylacetamide, N,N-dimethylacetamide, N-methylpyrrolidone, dimethylsulfoxide, benzylethylether, dihexylether, acetylacetone, isophorone, caproic acid, caprylic acid, 1-octanol, 1-nonanol, benzylalcohol, benzyl acetate, ethyl benzoate, diethyl oxalate, diethyl maleate, γ-butyrolactone, ethylene carbonate, propylene carbonate, phenyl cellosolve acetate, and the like may also be used.

Among these, considering compatibility and reactivity, ketones such as cyclohexanone; glycol ethers such as ethylene glycol monoethyl ether; ethylene glycol alkyl ether acetates such as ethyl cellosolve acetate; esters such as 2-hydroxy ethyl propionate; carbitols such as diethylene glycol monomethyl ether; and propylene glycol alkyl ether acetates such as propylene glycol monomethyl ether acetate and propylene glycol propyl ether acetate, may be used.

The solvent may be included in a balance amount, specifically about 30 wt % to about 95 wt %, more specifically about 75 wt % to about 94 wt %, for example about 80 wt % to about 90 wt %, for example about 85 wt % to about 90 wt %, based on a total amount of the photoresist composition. When the solvent is included within the above range, the photoresist composition may have an appropriate viscosity, thereby improving the processability during pattern formation.

Meanwhile, the photoresist composition may further include a surfactant in addition to the aforementioned components. When the above photoresist composition includes the surfactant, it may be preferable to include one or two or more types of surfactants including at least one of a fluorine atom and a silicon atom (a fluorine-based surfactant, a silicon-based surfactant, a surfactant having both fluorine atoms and silicon atoms).

The fluorine-based surfactant and/or silicone-based surfactant may include for example, EFTOP EF301, EF303 (manufactured by Shin-Akita Kasei Co., Ltd.), FLUORAD FC430, 431, 4430 (manufactured by Sumitomo 3M Co., Ltd.), MEGAFACE F171, F173, F176, F189, F113, F110, F177, F120, R⁰⁸ (manufactured by Dainippon Ink & Kagaku Kogyo Co., Ltd.), SURFLON S-382, SC101, 102, 103, 104, 105, 106 (manufactured by Asahi Glass Co., Ltd.), TROIZOL S-366 (manufactured by Troy Chemical Co., Ltd.), GF-300, GF-150 (manufactured by Toagosei Kagaku Co., Ltd.), SURFLON S-393 (manufactured by Seimi Chemical Co., Ltd.), F-Top EF121, EF122A, EF122B, RF122C, EF125M, EF135M, EF351, EF352, EF801, EF802, EF601 (manufactured by Gemco Co., Ltd.), PF636, PF656, PF6320, PF6520 (manufactured by OMNOVA), FTX-204G, 208G, 218G, 230G, 204D, 208D, 212D, 218D, 222D (manufactured by Neos Co., Ltd.). Polysiloxane polymer KP-341 (manufactured by Shin-Etsu Chemical Co., Ltd.) may also be used as a silicone-based surfactant.

For example, commercially available surfactants may include MEGAFACE F178, F-470, F-473, F-475, F-476, F-472 (manufactured by Dainippon Ink & Kagaku Kogyo Co., Ltd.), a copolymer of acrylates (or methacrylates) having a C₆F₁₃ group and (poly(oxyalkylene))acrylates (or methacrylates), a copolymer of acrylates (or methacrylates) having a C₃F₇ group and (poly(oxyethylene))acrylates (or methacrylates) and (poly(oxypropylene))acrylates (or methacrylates), etc.

These surfactants may be used alone or in combination.

A content of the surfactant may be greater than about 0 wt % and less than or equal to about 2 wt %, for example, greater than about 0 wt % and less than or equal to about 1.5 wt %, for example, greater than about 0 wt % and less than or equal to about 1 wt %, based on a total solid content (total amount excluding the solvent) of the photoresist composition.

The photoresist composition may further include a carboxylic acid onium salt. The carboxylic acid onium salt may be an iodonium salt or a sulfonium salt. The anion moiety may be a C1 to C30 linear, branched, monocyclic, or polycyclic alkylcarboxylic acid anion. More preferably, an anion of a carboxylic acid in which some or all of these alkyl groups are substituted with fluorine is preferred. The alkyl group may include an oxygen atom. This ensures transparency to light below 220 nm, improves sensitivity and resolution, and improves density dependency and exposure margin.

The anion of the fluorine-substituted carboxylic acid may include anions of fluoroacetic acid, difluoroacetic acid, trifluoroacetic acid, pentafluoropropionic acid, heptafluorobutyric acid, nonafluoropentanoic acid, perfluorododecanoic acid, perfluorotridecanoic acid, perfluorocyclohexanecarboxylic acid, and 2,2-bistrifluoromethylpropionic acid.

A content of the above carboxylic acid onium salt in the composition may generally be about 0.1 wt % to about 20 wt %, for example about 0.5 wt % to about 10 wt %, for example about 1 wt % to about 7 wt %, based on a total solid content of the photoresist composition.

The photoresist composition may further include a compound having a molecular weight of 3000 g/mol or less, which is decomposed by the action of an acid and thus has an increased solubility in an alkaline developer (hereinafter also referred to as a “dissolution-inhibiting compound”). As the dissolution-inhibiting compound, an alicyclic or aliphatic compound including an acid-decomposable group, such as a cholic acid derivative including an acid-decomposable group described in Proceeding of SPIE, 2724,355 (1996), is preferable so as not to reduce the permeability below 220 nm.

An amount of the dissolution-inhibiting compound may be about 3 wt % to about 50 wt %, for example, about 5 wt % to about 40 wt %, based on a total solid content of the photoresist composition.

The photoresist composition may further include, as necessary, a dye, a plasticizer, a photosensitizer, a light absorber, and a compound that promotes solubility in a developer (e.g., a phenol compound having a molecular weight of 1000 g/mol or less, an alicyclic or aliphatic compound having a carboxyl group).

Another embodiment provides a resist layer formed using the photoresist composition.

Another embodiment provides a pattern forming method including exposing the resist layer; and developing the exposed resist layer.

That is, the pattern forming method of the present invention is performed using the aforementioned photoresist composition.

Specifically, the pattern forming method of the present invention may include forming a layer (resist layer) of the aforementioned photoresist composition on a substrate (hereinafter also referred to as “process (1)” or “film forming process”), exposing the resist layer to light (hereinafter also referred to as “process (2)” or “exposure process”), and developing the resist layer irradiated with actinic light or radiation using a developer (hereinafter also referred to as “process (3)” or “exposure process”).

Hereinafter, each process is described in detail.

### Process (1): Film Formation Process

The order of process (1) is not particularly limited, but examples thereof include a method of coating the composition of the present invention onto a substrate and performing a curing treatment as necessary (coating method), and a method of forming a resist layer on a support and transferring the resist layer onto a substrate. Among these, the coating method is preferable because of its superior productivity.

The substrate is not particularly limited, and may be an inorganic substrate of silicon, SiN, SiO₂, or TiN, a coating-type inorganic substrate such as SOG (Spin on Glass), or a substrate generally used in a semiconductor manufacturing process such as IC, a circuit board manufacturing process such as liquid crystal and thermal head, and further, a substrate generally used in a lithography process of other photofabrication processes. Additionally, an anti-reflection film may be disposed between the resist layer and the substrate as needed. As an anti-reflection film, a known organic or inorganic anti-reflection film may be appropriately used.

The thickness of the above resist layer (active light-sensitive or radiation-sensitive film) is not particularly limited, but is preferably about 1 nm to about 500 nm, more preferably about 1 nm to about 100 nm, because it can form a fine pattern with higher precision. Among these, those less than about 80 nm are more preferable. By setting the solid content concentration in the composition to an appropriate range to have an appropriate viscosity and improving the applicability and film-forming properties, such a film thickness can be achieved.

### Process (2): Exposure Process

Process (2) is a process of exposing (irradiating with active light or radiation) the resist layer (active light-sensitive or radiation-sensitive film) formed in process (1).

The light used for exposure is not particularly limited, but examples thereof include infrared light, visible light, ultraviolet light, ultraviolet light, extreme ultraviolet light, X-rays, and electron beams. The light may be ultraviolet light having a wavelength of preferably about 250 nm or less, more preferably about 220 nm or less, and even more preferably about 1 to about 200 nm.

More specifically, examples thereof may include a KrF excimer laser (248 nm), an ArF excimer laser (193 nm), an F2 excimer laser (157 nm), an X-ray, an EUV (13 nm), and an electron beam, and among these, a KrF excimer laser, an ArF excimer laser, an EUV, or an electron beam is preferable.

In the exposure process, an immersion exposure method may be applied. The immersion exposure method may be combined with super-resolution techniques such as the phase shift method and the modified illumination method.

In addition, even when exposure is performed by a method other than immersion exposure, a top coat may be formed on the resist layer.

After the process (2) and before the process (3) described later, heat treatment (PEB: Post Exposure Bake) may be performed on the resist layer exposed in the process (2). The reaction of the exposed region is accelerated by this process. The heat treatment (PEB) may be performed multiple times.

The temperature of the heat treatment is preferably about 70° C. to about 130° C., more preferably about 80° C. to about 120° C.

The time of the heat treatment is preferably about 30 to about 300 seconds, more preferably about 30 to about 180 seconds, and still more preferably about 30 to about 90 seconds.

The heat treatment may be performed by means equipped in a conventional exposure developer, or may be performed using a hot plate, etc.

### Process (3): Phenomenon Process

The pattern forming process of the present invention has a developing process. As the developer, there is no particular limitation, and examples thereof may include an alkaline developer and a developer including an organic solvent.

The process (3) may be a process of developing the resist layer (resist layer irradiated with active light or radiation) exposed in the process (2) using an alkaline developer.

For the alkaline developer, it is preferable to use an alkaline aqueous solution including alkali. The type of the alkaline aqueous solution is not particularly limited, but examples thereof include an alkaline aqueous solution including a quaternary ammonium salt represented by tetramethylammonium hydroxide, an inorganic alkali, a primary amine, a secondary amine, a tertiary amine, an alcohol amine, or a cyclic amine. Among these, it is preferable that the alkaline developer be an aqueous solution of a quaternary ammonium salt, such as tetramethylammonium hydroxide (TMAH). An appropriate amount of alcohol, surfactant, etc. may be added to the alkaline developer. An alkali concentration of the alkaline developer is usually about 0.1 to about 20 mass %. Also, the pH of the alkaline developer is usually about 10.0 to about 15.0.

In addition, the process (3) may be a process of developing the resist layer (resist layer irradiated with active light or radiation) exposed in the process (2) using a developer including an organic solvent (hereinafter also referred to as “organic solvent developer”). Because the peeling and development of the top coat may be performed simultaneously, it is preferable to develop using a developer including an organic solvent.

As organic solvent developers, a polar solvent such as a ketone solvent, an ester solvent, an alcohol solvent, an amide solvent, and an ether solvent, as well as a hydrocarbon solvent may be used.

Examples of the ketone solvent may include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetylcarbinol, acetophenone, methyl naphthyl ketone, isophorone, and propylene carbonate.

Examples of the ester solvent may include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, methyl 2-hydroxyisobutyrate, isobutyl isobutyrate, butyl propionate, butyl butanoate, and isoamyl acetate.

Examples of the alcohol solvent may include alcohols such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, and n-decanol; glycol solvents such as ethylene glycol, diethylene glycol, and triethylene glycol; or glycol ether solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethyl butanol.

Examples of the ether solvent may include, in addition to the glycol ether solvent, dioxane, tetrahydrofuran, etc.

Examples of the amide solvent may include N-methyl-2-pyrrolidone, N, N-dimethylacetamide, N,N-dimethylformamide, hexamethylphosphoric triamide, and 1,3-dimethyl-2-imidazolidinone.

Examples of the hydrocarbon solvent may include aromatic hydrocarbon solvents such as toluene and xylene, and aliphatic hydrocarbon solvents such as pentane, hexane, octane, and decane.

The solvents may be used in combination, or mixed with water and a solvent other than the above. However, in order to sufficiently exhibit the effects of the present invention, it is preferable that the moisture content of the entire developer be less than about 10 mass %, and it is more preferable that it contains substantially no moisture.

That is, an amount of organic solvent used in the organic solvent developer is preferably about 90 mass % or more and about 100 mass % or less, and more preferably about 95 mass % or more and about 100 mass % or less, based on the total amount of the developer.

The vapor pressure of the organic solvent developer is preferably about 5 kPa or less, more preferably about 3 kPa or less, and even more preferably about 2 kPa or less at 20° C. When the vapor pressure of the organic solvent developer is set to about 5 kPa or less, evaporation of the developer on the substrate or within the developing cup is suppressed, temperature uniformity within the substrate surface is improved, and as a result, dimensional uniformity within the substrate surface is improved.

An appropriate amount of surfactant may be added to the organic solvent developer as needed.

An amount of surfactant used may be typically about 0.001 wt % to about 5 wt %, preferably about 0.005 wt % to about 2 wt %, and more preferably about 0.01 wt % to about 0.5 wt %, based on the total amount of the developer.

The organic solvent developer may include a basic compound. Specific examples and preferred examples of the basic compound that the organic solvent developer used in the present invention may include are the same as those of the basic compound that the composition may include as the acid diffusion control agent described above.

As the developing method, for example, a method of immersing the substrate in a tank filled with a developer for a certain period of time (dip method), a method of developing by raising the developer on the substrate surface by surface tension and leaving it there for a certain period of time (puddle method), a method of spraying the developer on the substrate surface (spray method), and a method of continuously discharging the developer while scanning the developer discharging nozzle at a certain speed on a substrate rotating at a certain speed (dynamic dispensing method) can be applied. In addition, there are no particular limitations on the appropriate range of discharge pressure of the discharged developer, and the method for adjusting the discharge pressure of the developer.

In one aspect of the pattern forming method of the present invention, a process of developing using an organic solvent developer (organic solvent developing process) and a process of developing using an alkaline aqueous solution (alkali developing process) may be used in combination. This allows for fine patterns to be formed.

In one aspect of the pattern forming method of the present invention, the order of the alkali development process and the organic solvent development process is not particularly limited, but it is more preferable to perform the alkali development process before the organic solvent developing process.

After the developing process using a developer, it is preferable to include a cleaning process using a rinse solution. Examples of rinse solutions used in the rinsing process after the developing process using an alkaline developer include pure water. Additionally, an appropriate amount of surfactant may be added to the pure water.

In addition, the pattern forming method of the present invention may include a heating process (post bake) after the rinsing process. The developer and rinse solution remaining between and within the patterns are removed by baking. The heating process after the rinsing process is usually performed at about 40 to about 160° C., preferably about 70 to about 95° C., for usually about 10 seconds to about 3 minutes, preferably about 30 to about 90 seconds.

Hereinafter, the embodiments are illustrated in more detail with reference to examples. These examples, however, are not in any sense to be interpreted as limiting the scope of the invention.

### Example 1: Synthesis of Compound Represented by Chemical Formula 1A

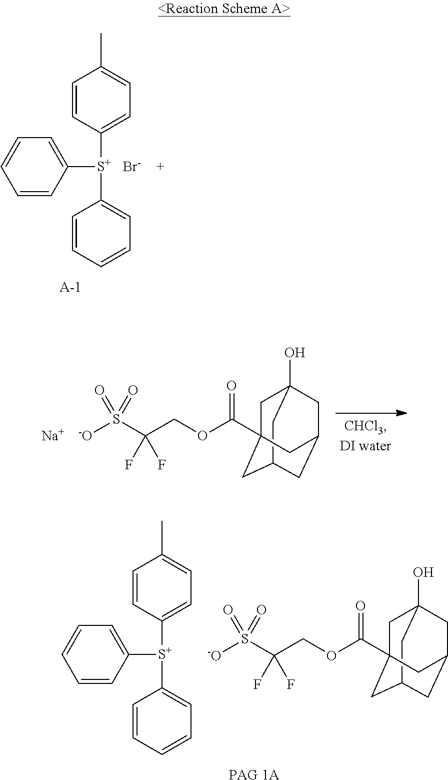

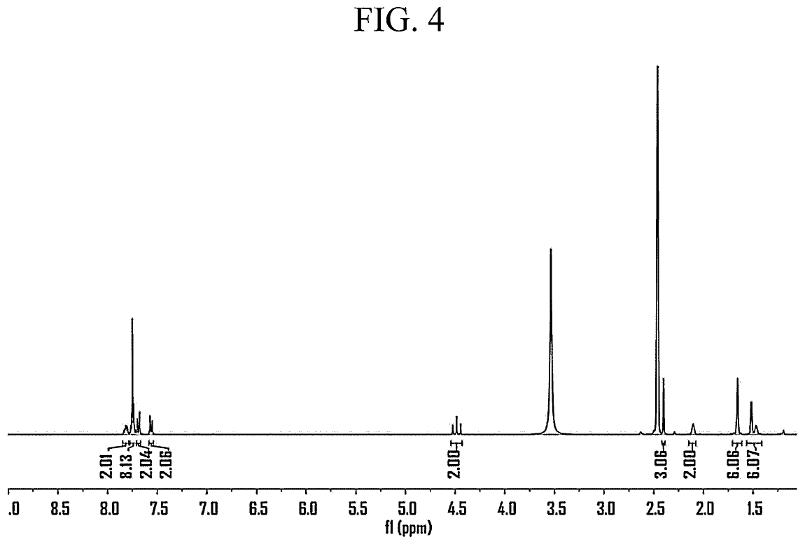

Compound A-1 (8.43 g, 23.60 mmol) and 1,1-difluoro-2-(3-hydroxy-adamantane-1-carbonyloxy)-ethanesulfonic sodium salt (8.51 g, 23.60 mmol) were mixed in 45 mL of chloroform and 5 ml of water and then, stirred for 24 hours. Subsequently, an organic layer was separated therefrom and then, dried with MgSO₄ and filtered, a filtrate therefrom was treated under a reduced pressure, and a residue therefrom was separated and purified through silica gel column chromatography to obtain a compound represented by Chemical Formula 1A (Yield: 12.01 g, 82.5%, Purity: 99.2%). ¹H-NMR 5 (400 MHz, CDCl₃) data are shown in FIG. 4.

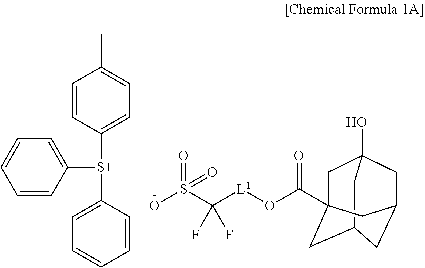

### Example 2: Synthesis of Compound Represented by Chemical Formula 1B

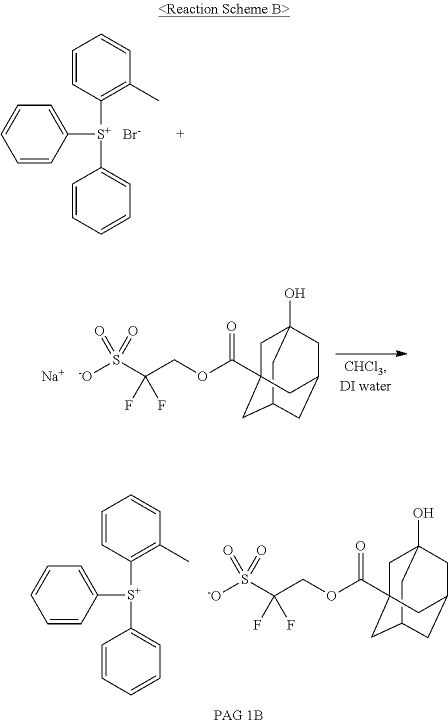

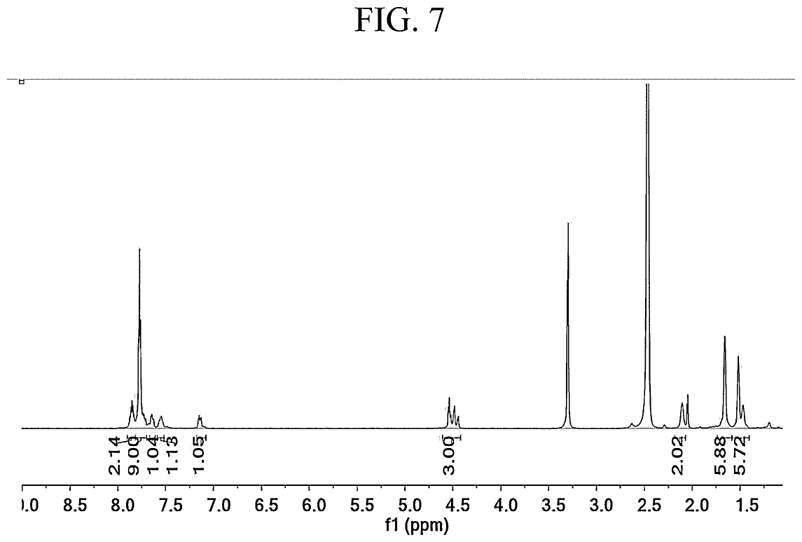

Diphenyl-o-tolyl-sulfonium bromide (8.43 g, 23.60 mmol) and 1,1-difluoro-2-(3-hydroxy-adamantane-1-carbonyloxy)-ethanesulfonic sodium salt (8.51 g, 23.60 mmol) instead of Compound A-1 are mixed with 45 mL of chloroform and 5 ml of water and then, stirred for 24 hours. Subsequently, a compound represented by Chemical Formula 1B (Yield: 11.45 g, 78.7%, Purity: 98.0%) was obtained in the same manner as in Reaction Scheme A. ¹H-NMR (400 MHz, CDCl₃) data are shown in FIG. 7.

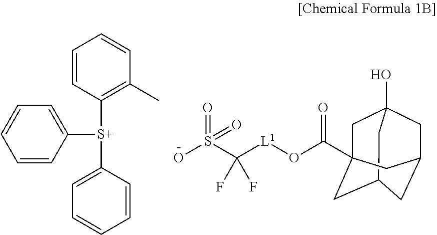

### Example 3: Synthesis of Compound Represented by Chemical Formula 1C

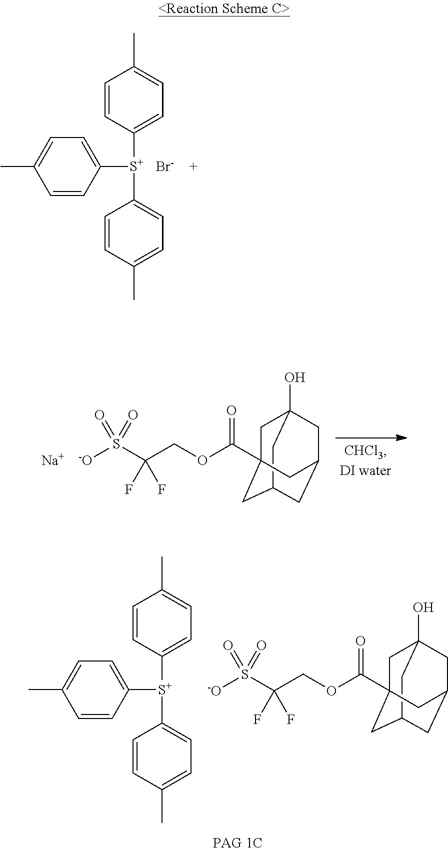

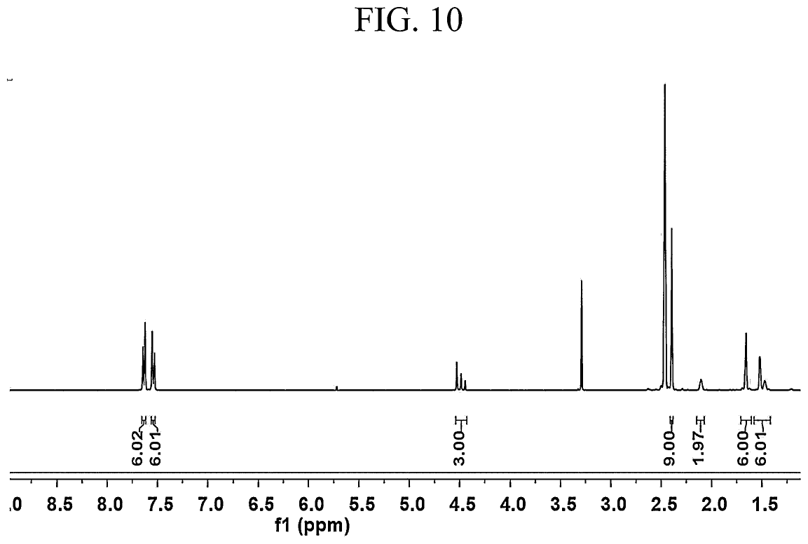

Tri-p-tolyl-sulfonium bromide (9.09 g, 23.60 mmol) and 1,1-difluoro-2-(3-10 hydroxy-adamantane-1-carbonyloxy)-ethanesulfonic sodium salt (8.51 g, 23.60 mmol) instead of Compound A-1 were mixed with 45 mL of chloroform and 5 ml of water and then, stirred for 1 hour. Subsequently, a compound represented by Chemical Formula 1C (Yield: 11.38 g, 74.8%, Purity: 96.9%) was obtained through the same separation and purification as in Reaction Scheme A. ¹H-NMR (400 MHz, CDCl₃) data are shown in FIG. 10.

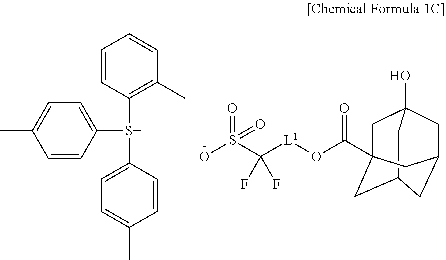

### Comparative Example 1: Synthesis of Compound Represented by Chemical

Formula C-1

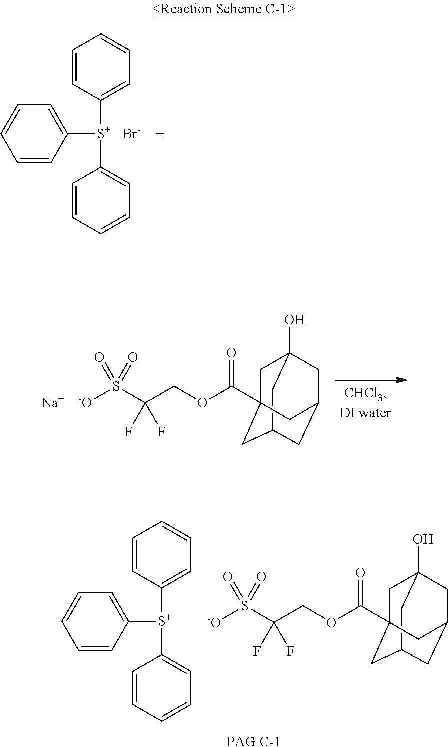

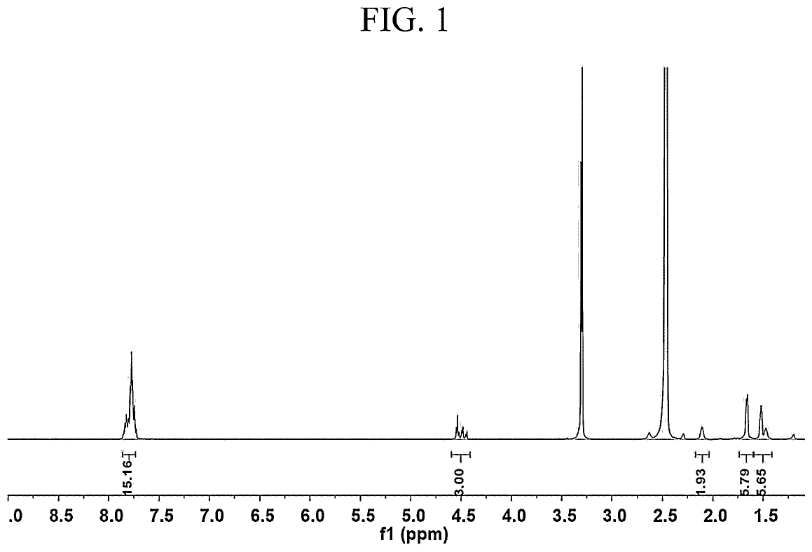

Triphenyl sulfonium bromide (8.10 g, 23.60 mmol) and 1,1-difluoro-2-(3-hydroxy-adamantane-1-carbonyloxy)-ethanesulfonic sodium salt (8.51 g, 23.60 mmol) instead of Compound A-1 were mixed with 45 mL of chloroform and 5 ml of water and then, stirred for 1 hour. Subsequently, a compound represented by Chemical Formula C-1 (Yield: 12.3 g, 86.5%, Purity: 99.0%) was obtained through the same separation and purification as in Reaction Scheme A. ¹H-NMR (400 MHz, CDCl₃) data are shown in FIG. 1.

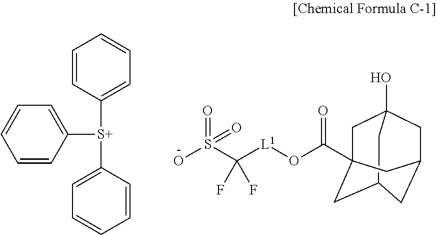

### Comparative Example 2: Synthesis of Compound Represented by Chemical Formula C-2

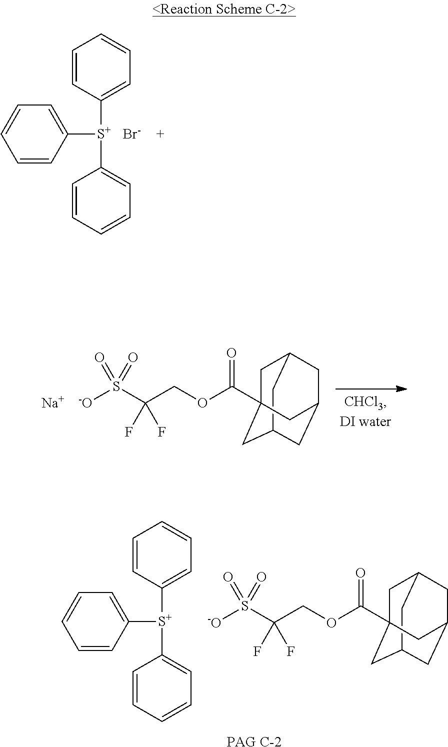

Triphenyl sulfonium bromide (8.10 g, 23.60 mmol) and 2-(adamantane-1-carbonyloxy)-1,1-difluoro-ethanesulfonic sodium salt (7.63 g, 23.60 mmol) instead of Compound A-1 were mixed with 45 mL of methylene chloride and 5 ml of water and then, stirred for 1 hour. Subsequently, a compound represented by Chemical Formula C-2 (Yield: 12.95 g, 93.5%, Purity: 99.3%) was obtained through the same separation and purification as in Reaction Scheme A.

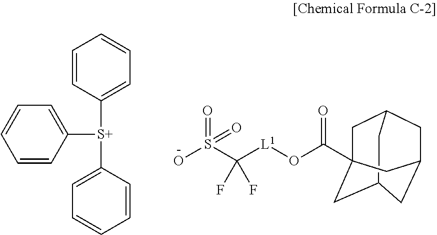

### Comparative Example 3: Synthesis of Compound Represented by Chemical Formula C-3

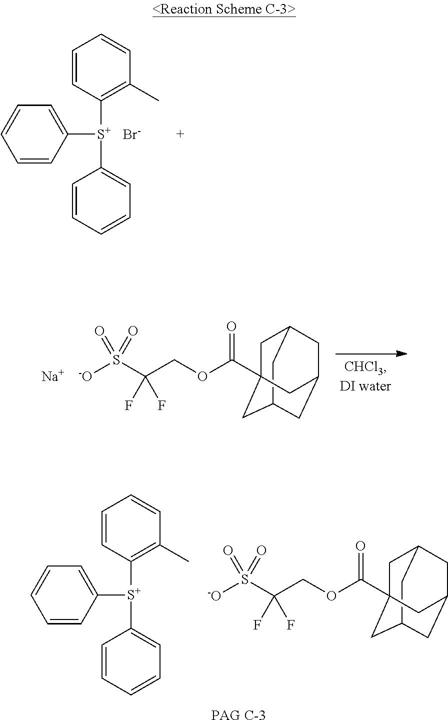

Diphenyl-o-tolyl-sulfonium bromide (8.43 g, 23.60 mmol) and 2-(adamantane-1-carbonyloxy)-1,1-difluoro-ethanesulfonic sodium salt (7.63 g, 23.60 mmol) instead of Compound A-1 were mixed with 45 mL of methylene chloride and 5 ml of water and then, stirred for 1 hour. Subsequently, a compound represented by Chemical Formula C-3 (Yield: 12.4 g, 87.5%, Purity: 99.2%) was obtained through the same separation and purification as in Reaction Scheme A.

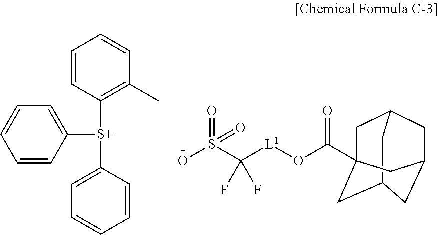

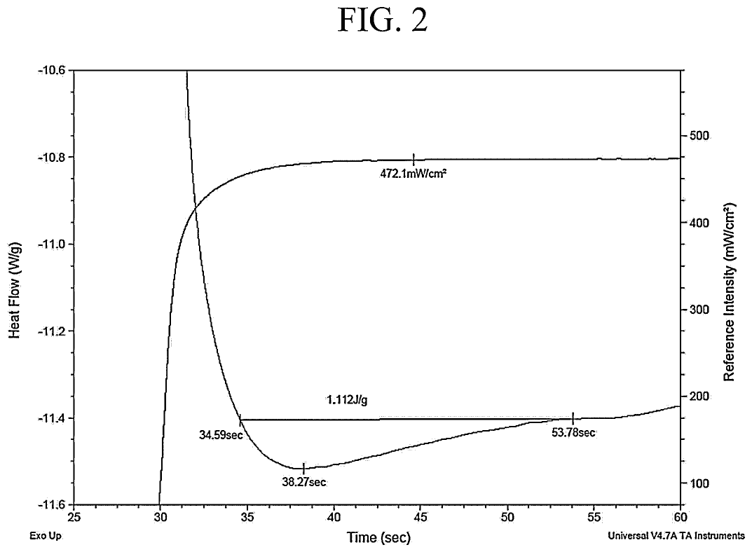

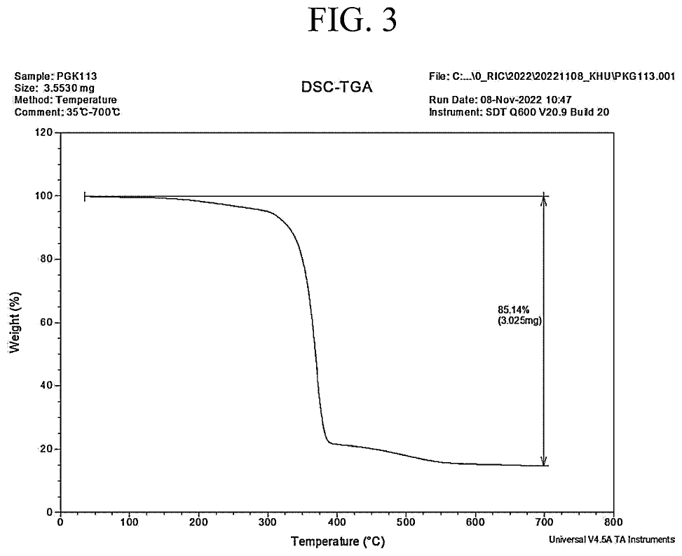

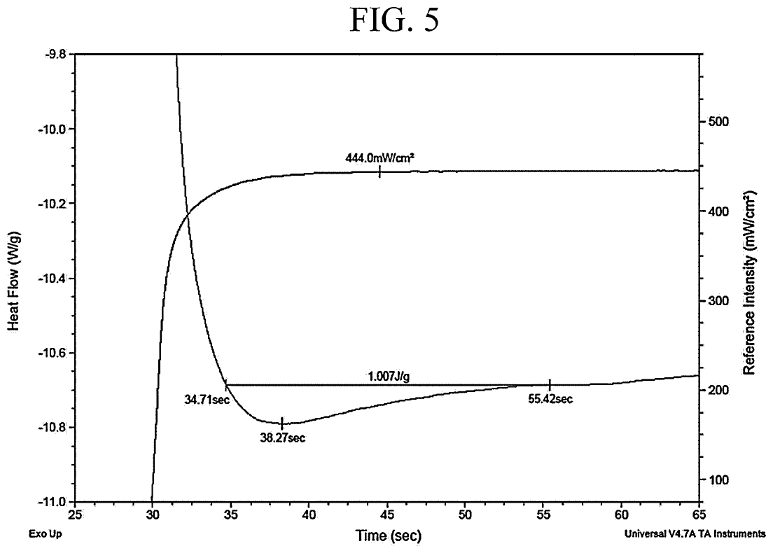

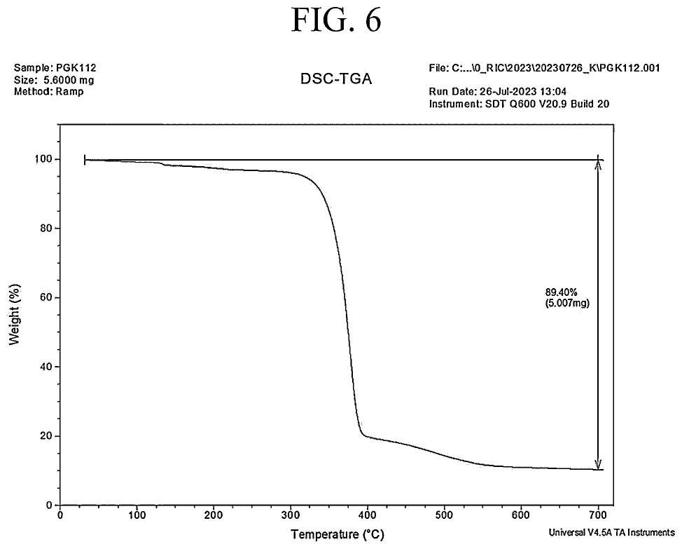

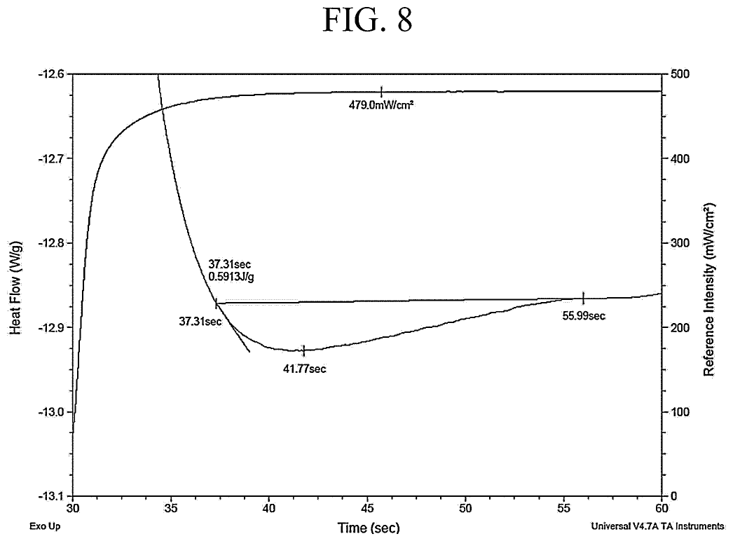

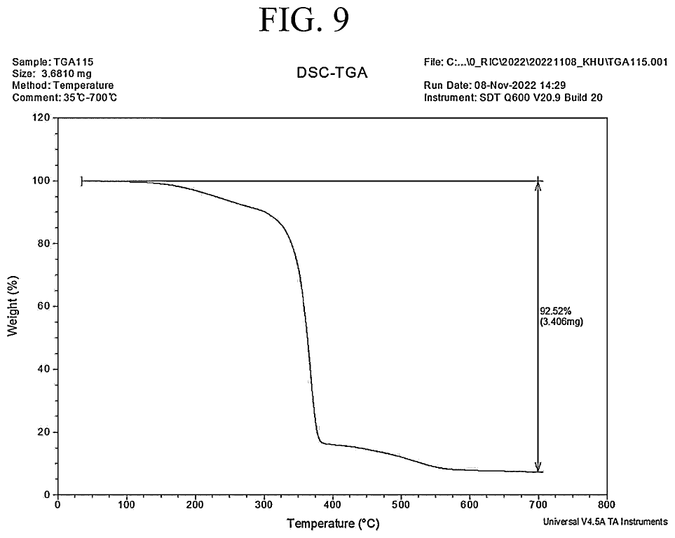

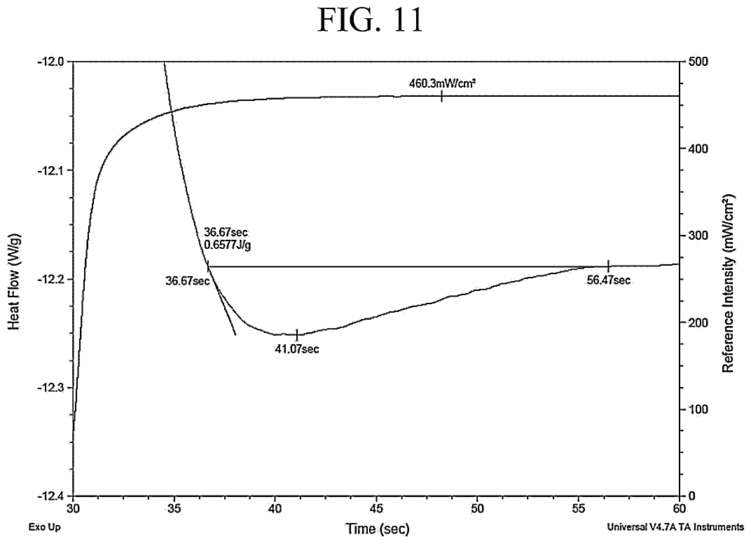

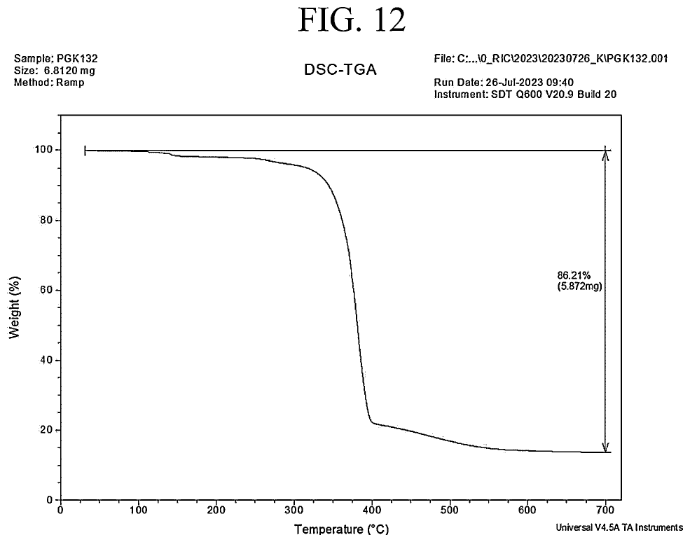

NMR data, DSC data, TGA data and Mulliken constant calculation values of the compounds according to Examples 1 to 3 and Comparative Example 1 are shown in FIGS. 1 to 12 and Tables 1 and 2.

TABLE 1

| | Comparative | | | |
|---|---|---|---|---|
| | Example 1 | Example 1 | Example 2 | Example 3 |
| Enthalpy (J/g) | 1.112 | 1.007 | 0.5913 | 0.6577 |
| Enthalpy (J/mol) | 670.213 | 621.057 | 364.678 | 424.078 |
| Peak (sec) | 38.27 | 38.27 | 41.77 | 41.07 |

TABLE 2

| | Comparative | | | |
|---|---|---|---|---|
| Sulfonium belongs to | Example 1 | Example 1 | Example 2 | Example 3 |
| Charge of S+ | +0.23 | +0.15 | +0.08 | +0.09 |
| by Mulliken § | | | | |

§ Mulliken population analysis

Referring to FIGS. 1 to 12 and Tables 1 and 2, as a result of checking a peak time period (sec), Example 1 was the same as Comparative Example 1, but a peak appeared later in Examples 2 and 3, Examples 1 and 3 were confirmed to exhibit good reactivity, and Example 1 and Comparative Example 1 exhibited almost the same enthalpy (J/mol), but Examples 2 and 3 exhibited clearly lower enthalpy in the 300s or 400s, which confirmed that the reactivity was deteriorated. An increase in Mulliken charge value means an increase in S+ electron charge, wherein when a Mulliken constant was calculated, Example 1 exhibited a larger Mulliken value than Examples 2 and 3, which showed that when one methyl group was present at a para position, electron density of S+ further increased, and thus reactivity increased. The TGA results also confirmed that Example 1 was superior to Comparative Example 1. In summary, a photoacid generator capable of forming a pattern with an excellent shape as well as maintaining stability was confirmed to have the structures of Examples 1 to 3 and desirably, the structure of Example 1.

### Preparation of Photoresist Compositions

### Example 4

An acrylic polymer (SP-RY-25, Showa Denko K.K.), a solvent (PGMEA), and the photoacid generator of Example 1 were mixed in each amount of 10 wt %, 89 wt %, and 1 wt % to prepare a photoresist composition.

### Example 5

As photoresist composition was prepared in the manner as in Example 1 except that the photoacid generator of Example 2 was used instead of the photoacid generator of Example 1.

### Example 6

As photoresist composition was prepared in the manner as in Example 1 except that the photoacid generator of Example 3 was used instead of the photoacid generator of Example 1.

### Comparative Example 4

As photoresist composition was prepared in the manner as in Example 1 except that the photoacid generator of Comparative Example 1 was used instead of the photoacid generator of Example 1.

### Comparative Example 5

As photoresist composition was prepared in the manner as in Example 1 except that the photoacid generator of Comparative Example 2 was used instead of the photoacid generator of Example 1.

### Comparative Example 6

As photoresist composition was prepared in the manner as in Example 1 except that the photoacid generator of Comparative Example 3 was used instead of the photoacid generator of Example 1.

### Evaluation

The photoresist compositions according to Examples 4 to 6 and Comparative Examples 4 to 6 were coated to be 1 μm to 3 μm thick on a 1 mm-thick degreased glass substrate at 250 rpm to 350 rpm and then, dried at 90° C. on a hot plate for 2 minutes to obtain films. After performing ArF-immersion (ASML) exposure at 40 mJ/cm², the films were developed for 60 seconds by using a (111 times diluted) KOH developer under a ratio condition of a washing solution/developer=1/0.8 and washed again for 60 seconds to provide development history. Subsequently, the obtained films were dried at 230° C. in a forced convection drying furnace for 20 minutes to obtain patterns.

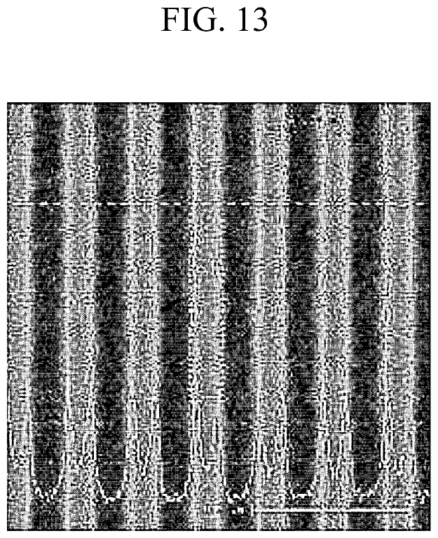

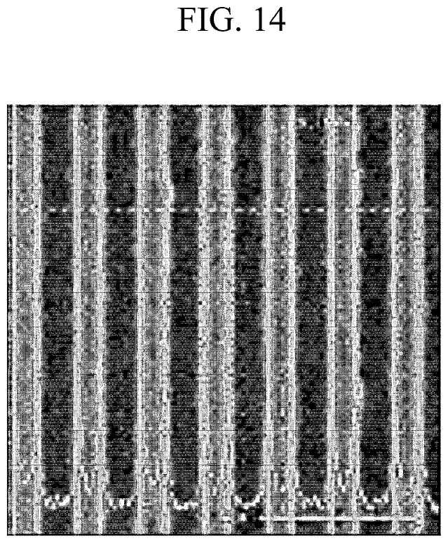

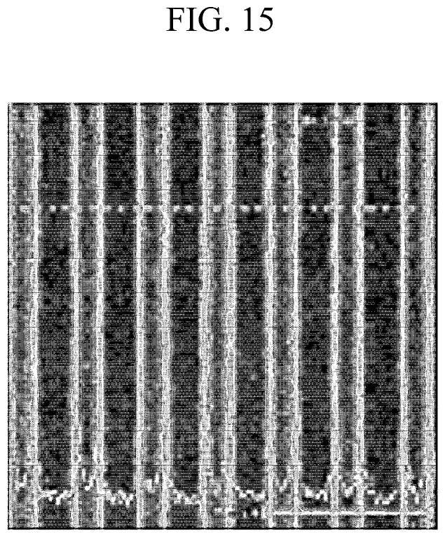

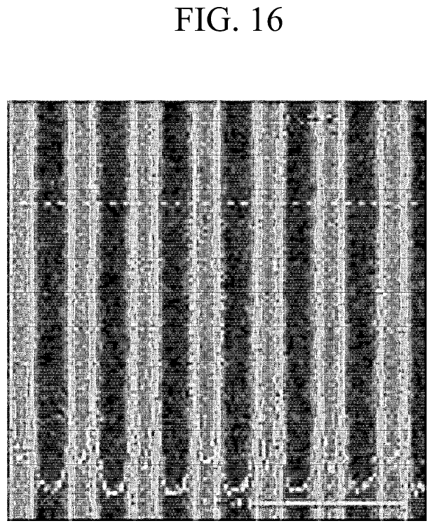

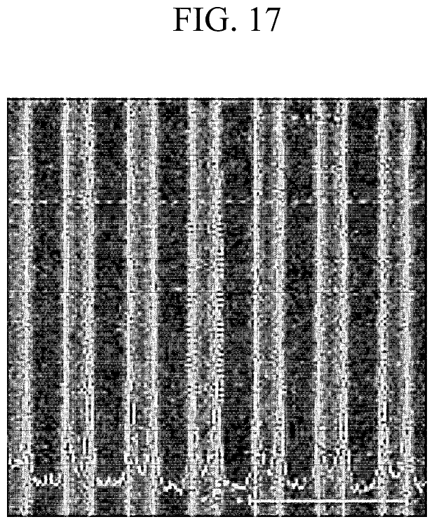

The patterns were taken an image of by using CD-SEM (Hitachi, Ltd.), and the results are shown in FIGS. 13 to 17. In addition, the patterns were measured with respect to line width roughness (LWR), energy of optimum (EOP, mJ/cm²), and exposure latitude (EL, %), and the results are shown in Table 3. The higher EL %, the better margin.

TABLE 3

| | | | | Comp. | Comp. | Comp. |
|---|---|---|---|---|---|---|
| | Ex. 4 | Ex. 5 | Ex. 6 | Ex. 4 | Ex. 5 | Ex. 6 |
| LWR (nm) | 2.2 | 3.3 | 2.8 | 3.4 | 3.6 | 3.82 |
| EOP | 23 | 35 | 29 | 37 | 40 | 45 |
| (mJ/cm²) | | | | | | |
| EL (%) | 30 | 20 | 20 | 18 | 9.8 | 7.8 |

Referring to FIGS. 13 to 17 and Table 3, when a methyl group was at a position of ortho, LWR was deteriorated due to steric hindrance effects, and EOP (sensitivity) also was disadvantageous (increased). Furthermore, when a hydroxy group was introduced, LWR was overall improved, and EOP (sensitivity) was also improved (decreased). Herein, when the methyl group was introduced at the para position of cations, and the hydroxy group was introduced into an adamantyl group, the most excellent LWR, EOP, and EL were simultaneously obtained, which confirmed that the most excellent pattern was formed.

While this invention has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims. Therefore, the aforementioned embodiments should be understood to be exemplary but not limiting the present invention in any way.

What is claimed is:

1. A photoacid generator including a compound represented by Chemical Formula 1: 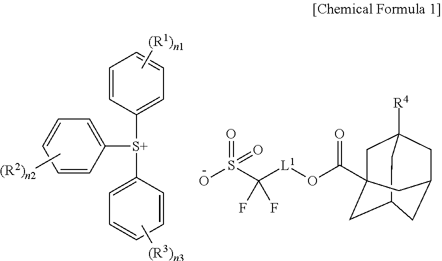
wherein, in Chemical Formula 1,
R¹ to R⁴ are each independently a halogen atom, a hydroxy group, a substituted or unsubstituted C1 to C20 alkyl group, a substituted or unsubstituted C1 to C20 alkoxy group, a substituted or unsubstituted C3 to C20 cycloalkyl group, a substituted or unsubstituted C6 to C20 aryl group, or a substituted or unsubstituted C2 to C20 heterocyclic group,
L¹ is a single bond, a substituted or unsubstituted C1 to C20 alkylene group or a substituted or unsubstituted C6 to C20 arylene group, and
n1 to n3 are each independently an integer from 0 to 5, provided that n1+n2+n3 ≠0.

2. The photoacid generator of claim 1, wherein Chemical Formula 1 is represented by Chemical Formula 1-1: 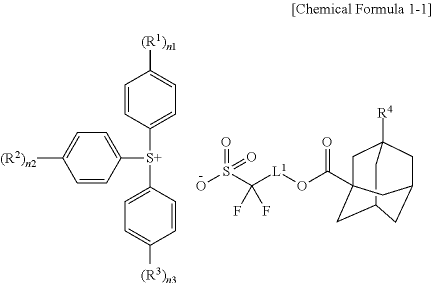
wherein, in Chemical Formula 1-1,
R¹ to R⁴ are each independently a halogen atom, a hydroxy group, a substituted or unsubstituted C1 to C20 alkyl group, a substituted or unsubstituted C1 to C20 alkoxy group, a substituted or unsubstituted C3 to C20 cycloalkyl group, a substituted or unsubstituted C6 to C20 aryl group, or a substituted or unsubstituted C2 to C20 heterocyclic group,
L¹ is a single bond, a substituted or unsubstituted C1 to C20 alkylene group or a substituted or unsubstituted C6 to C20 arylene group, and
n1 to n3 are each independently an integer of 0 or 1, provided that n1+n2+n3≠0.

3. The photoacid generator of claim 1, wherein
the n1+n2+n3 is 1.

4. The photoacid generator of claim 3, wherein
the n1 is an integer of 1 and the n2 and n3 are each independently an integer of 0.

5. The photoacid generator of claim 1, wherein
R¹ to R³ are each independently a substituted or unsubstituted C1 to C20 alkyl group.

6. The photoacid generator of claim 1, wherein
R⁴ is a hydroxy group.

7. The photoacid generator of claim 1, wherein
L¹ is a substituted or unsubstituted C1 to C20 alkylene group.

8. The photoacid generator of claim 1, wherein
the compound represented by the above Chemical Formula 1 is represented by Chemical Formula 1A, Chemical Formula 1B or Chemical Formula 1C:

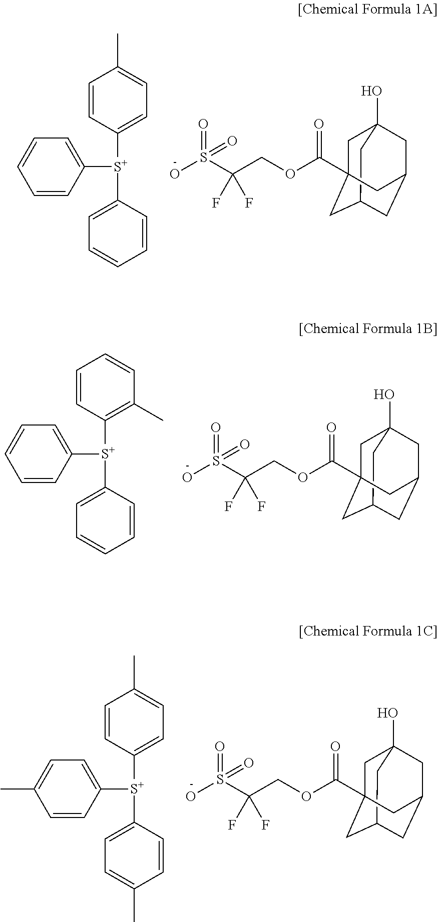 [SMILES: Cc1ccc([S+](c2ccccc2)c2ccccc2)cc1 ; O=C(OCC(F)(F)S(=O)(=O)O)C12CC3CC(CC(O)(C3)C1)C2 ; Cc1ccccc1[S+](c1ccccc1)c1ccccc1 ; O=C(OCC(F)(F)S(=O)(=O)O)C12CC3CC(CC(O)(C3)C1)C2 ; Cc1ccc([S+](c2ccc(C)cc2)c2ccc(C)cc2)cc1 ; O=C(OCC(F)(F)S(=O)(=O)O)C12CC3CC(CC(O)(C3)C1)C2]

9. A photoresist composition, comprising
a resin;
the photoacid generator of claim 1; and
a solvent.

10. The photoresist composition of claim 9, wherein
the resin comprises an acrylic resin.

11. The photoresist composition of claim 9, wherein
the photoresist composition comprises, based on a total amount of the photoresist composition,
about 5 wt % to about 20 wt % of the resin;
about 0.1 wt % to about 5 wt % of the photoacid generator; and
a balance amount of the solvent.

12. A resist layer formed using the photoresist composition of claim 9.
